(19) United States
(12) Patent Application Publication
(10) Pub. No.: US 2023/0288263 A1
(43) Pub. Date: Sep. 14, 2023

(54) MICROBOLOMETER WITH ENHANCED OPERATIONAL CHARACTERISTICS AND METHOD OF FABRICATION THEREOF

(71) Applicant: Abdulilah Mayet, Jeddah (SA)

(72) Inventor: Abdulilah Mayet, Jeddah (SA)

(21) Appl. No.: 18/092,173

(22) Filed: Dec. 30, 2022

Related U.S. Application Data
(60) Provisional application No. 63/318,065, filed on Mar. 9, 2022.

(51) Int. Cl. G01J 5/20; C23C 14/06

(52) U.S. Cl. CPC G01J 5/20; C23C 14/0641; C23C 14/34

(57) ABSTRACT

A system for advanced microbolometer performance is provided comprising an absorber element and a detector comprising a film coated on at least one side of the absorber element. The detector detects variation in temperature of the absorber element and changes electrical resistance in response to the detected variation. The film is an inorganic compound. The inorganic compound is αWNx comprising amorphous tungsten nitride. The absorber element varies temperature responsive to IR (infrared radiation) incident on the absorber element. The film is dangled over a readout integrated circuit (ROIC) at a height of two to three microns. The microbolometer further comprises electrodes coupled to a silicon substrate. The coupling of the electrodes to the substrate provides structural support for the dangled inorganic compound. The electrodes further provide electrical connectivity.

### CROSS REFERENCE TO RELATED APPLICATIONS

The present Non-Provisional Patent Application is related to U.S. Provisional Pat. Application No. 63318065 filed Mar. 9, 2022, the contents of which are incorporated herein in their entirety.

### FIELD OF THE DISCLOSURE

The present disclosure is in the field of micro-electromechanical system structures. More particularly, the present disclosure provides a microbolometer with enhanced operational characteristics and further provides cost effective methods of fabrication thereof.

### BACKGROUND

A microbolometer is an array of heat detecting sensors that are sensitive to infrared radiation. As infrared energy strikes an individual microbolometer element, the element increases in temperature, and its electrical resistance changes. This resistance change is measured and then processed into temperature values which can be represented graphically in a thermal image.

The microbolometer presently available publicly is an uncooled infrared sensor. A detector array does not need to be cooled to produce sensitive thermal images. Photon detectors, infrared detectors, may improve thermal sensitivity but require the detector to be cooled to cryogenic temperatures utilizing cooling methods such as Stirling cycle engines and liquid nitrogen. The use of photon detectors increases the cost of infrared cameras, decreases ease-of-use, and leads to more frequent and expensive maintenance.

Existing microbolometers are fabricated mainly from amorphous silicon, vanadium and vanadium oxide, and titanium. The fabrication process of these materials is not compatible with CMOS (Complementary Metal Oxide Semiconductor) fabrication. Therefore, a specialized fabrication facility is required to fabricate the microbolometers on top of the ROIC (readout integrated circuit), manufactured in a standard CMOS fab facility. Thus, the present technique of fabrication is a sophisticated and complicated process that in turn raises the cost of the microbolometers and IR (Infrared) imagers. Further, existing microbolometers provide lower operational characteristic due to the average TCR (temperature coefficient of resistance) value, responsiveness, and conductivity.

### BRIEF DESCRIPTION OF THE FIGURES

FIG. 1A illustrates a side view of an exemplary elevated microbolometer with enhanced operational characteristics in accordance with an embodiment of the present disclosure.

FIG. 1B illustrates an exemplary elevated microbolometer enhanced operational characteristics and FPA in accordance with an embodiment of the present disclosure.

FIG. 2 illustrates an exemplary process of fabricating a crystalline cluster-free inorganic compound such as αWNx (amorphous tungsten nitride) film in accordance with an embodiment of the present disclosure.

### DETAILED DESCRIPTION

Systems and methods described herein provide a microbolometer with enhanced operational characteristics and cost effective, monolithic CMOS (complementary metal-oxide semiconductor) compatible method of fabrication thereof. The microbolometer provided herein exhibits high TCR value, responsive and conductivity. Systems and methods further provide a cost-effective method of fabrication of microbolometer in situ with the CMOS (Complementary Metal Oxide Semiconductor) based ROIC fabrication.

The microbolometer provided herein be used as a vacuum sensor relying on variations in resistivity against heat dissipation from sensors. The microbolometer provided herein exhibits enhanced operational characteristics compatible with CMOS (Complementary Metal Oxide Semiconductor) fabrication.

The microbolometer includes an absorber element that varies temperature responsive to IR (infrared radiation) incident on it. A film of an inorganic compound such as α-WNx (amorphous tungsten nitride) coated on at least one side of the absorber element, the inorganic compound acts as a detector. The ROIC (readout integrated circuit) part of silicon substrate, and detector changes electrical resistance in response to the variation in temperature of the absorber element.

The film of inorganic compound such as α-WNx is dangled over the ROIC at a height of 2-3 microns. The microbolometer further comprises electrodes coupled to the silicon substrate providing structural support for the dangling inorganic compound which is the αWNx detector and further provides electrical connectivity.

Systems and methods further provide a Crystalline cluster-free film of inorganic compound such as amorphous α-WNx Tungsten nitride alloy. The film is fabricated from a mixture of Tungsten metal atoms and inert gas mixture of Nitrogen and argon atoms. The mixture is deposited such that a totally crystalline cluster-free amorphous Tungsten nitride alloy film is created. The crystalline cluster-free amorphous Tungsten nitride alloy film retains its crystalline cluster-free amorphous structure at most temperatures.

A method includes sputtering a substrate using a Tungsten target. The method includes the steps of placing a substrate in a sputtering chamber and placing an inorganic compound such as αWNx (amorphous tungsten nitride) on a sputtering tool inside the sputtering chamber. The method also includes selecting a separation distance between the inorganic compound target and the maximized substrate to minimize adsorbed atom mobility of the crystalline cluster-free inorganic compound film deposited due to sputtering.

The method also includes adjusting a chamber pressure within an adequate range and adjusting sputtering gas mixture ratio, wherein the sputtering gas mixture comprises inert gases such as of Argon and Nitrogen. The method also includes adjusting sputtering power of the sputtering tool of 300W of alternating current.

The microbolometer includes an absorber element that varies temperature responsive to IR (infrared radiation) incident on it. A film of an inorganic compound such as αWNx (amorphous tungsten nitride) is coated on at least one side of the absorber element, the inorganic compound acting as a detector. The film is of inorganic compound such as αWNx and is dangled over the ROIC at a height of 2-3 microns. The microbolometer further comprises electrodes coupled to the silicon substrate providing structural support for the dangling inorganic compound which is the αWNx detector and further provides electrical connectivity.

Systems and methods provided herein further provide a Crystalline cluster-free film of inorganic compound such as amorphous α-WNx Tungsten nitride alloy. The film is fabricated from a mixture of Tungsten metal atoms and inert gas mixture of Nitrogen and argon atoms. The mixture is deposited in such a way that a crystalline cluster-free amorphous Tungsten nitride alloy film is created. The crystalline cluster-free amorphous Tungsten nitride alloy film retains its crystalline cluster-free amorphous structure at most temperatures.

Methods provided herein further include sputtering a substrate using a Tungsten target. The steps include placing a substrate in a sputtering chamber, placing an inorganic compound such as αWNx (amorphous tungsten nitride) on a sputtering tool inside the sputtering chamber, and selecting a separation distance between the inorganic compound target and the maximized substrate to minimize adsorbed atom mobility of the crystalline cluster-free inorganic compound film deposited due to sputtering.

Methods also include adjusting a chamber pressure within an adequate range, adjusting sputtering gas mixture ratio, wherein the sputtering gas mixture comprises inert gases such as of Argon and Nitrogen. Methods further include adjusting sputtering power of the sputtering tool of 300W of alternating current. The method is cost effective.

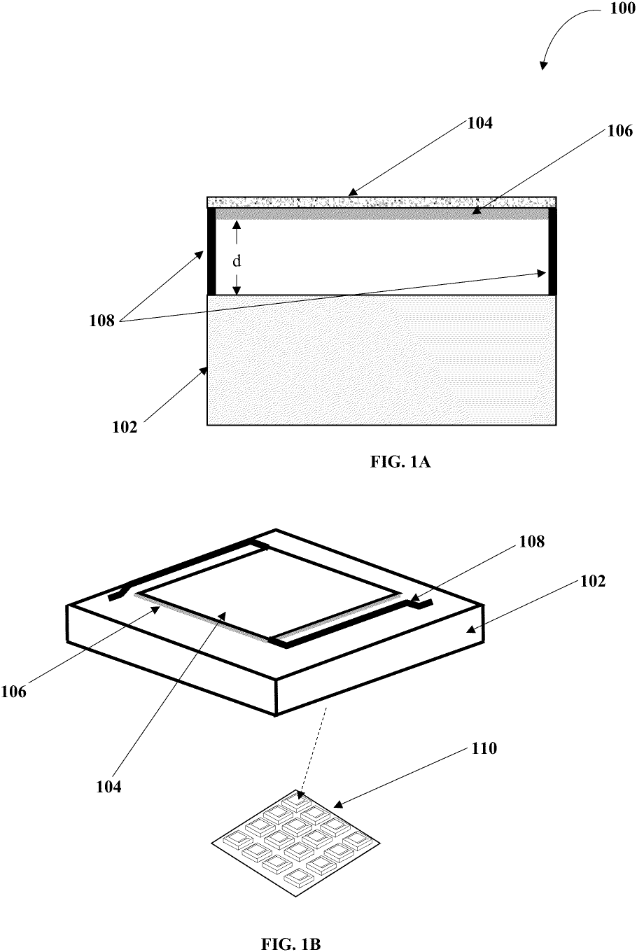

FIG. 1A provides a side view of an exemplary elevated microbolometer with enhanced operational characteristics in accordance with an embodiment of the present disclosure. A microbolometer 100 with enhanced operational characteristics includes a film of an inorganic compound such as αWNx 106. The αWNx 106 film has properties such as a TCR ≈ -1.9% /°C, low noise value and stable, and high reproducibility properties.

The αWNx 106 based microbolometer 100 includes an absorber element 104 to absorb infrared radiation. A deposition process of the αWNx 106 is compatible with CMOS fabrication processes. Compatibility of the αWNx 106 with CMOS fabrication processes may enables a complete imager to be fabricated in a single fabrication process.

The αWNx 106 dangles above the silicon substrate 102 and changes electrical resistance in response to the absorber element 104 changing temperature. The microbolometer 100 also includes electrode arms 108 coupled to a silicon substrate 102 to provide structural support for the αWNx detector 106 above the silicon substrate’s 102 surface. The electrode arms 108 further offer electrical connectivity for the microbolometer 100. The microbolometer 100 may be used as a vacuum sensor relying on variations in resistivity against heat dissipation from sensors.

The αWNx 106 is compatible with the CMOS fabrication process. Therefore, the microbolometer 100 FPA (Focal Plane array) 110 (as shown in FIG. 1B) would be carried out in a fabrication similar to that used for manufacturing the ROIC (CMOS Fabrication). The achievement of αWNx 106 being compatible with the CMOS fabrication process may lower the cost of IR imagers on an enormous scale and make them handy for numerous applications. The film of the αWNx 106 is dangled over the ROIC at a height of 2-3 microns.

The microbolometer 100 involves an absorber element 104 that varies the temperature in response to incident infrared radiation and an αWNx 106 detector dangled above the ROIC part of the silicon substrate 102 at a distance ‘d’ the value of ‘d’ can be of range of 2 to 3 microns. The αWNx detector 106 changes electrical resistance in response to the absorber element 104 changing temperatures. The microbolometer 100 further includes electrode arms 108 coupled to the silicon substrate 102 providing structural support for the dangling αWNx 106 detector and electrical connectivity. The film of the αWNx 106 is dangled over the ROIC at a height of 2-3 microns.

Microbolometer 100 IR FPA 110 and at least one microbolometer 100 may be configured to measure the vacuum of a package. Systems and methods provide an integrated microbolometer 100 IR focal plane array (FPA) 110 and vacuum sensor and associated fabrication method suitable for high-volume commercial vacuum packages. The microbolometer 100 pixel may operate as a vacuum sensor by measuring material resistance. The temperature variance degree for a given material depends on heat transfer efficiency from the material to the surrounding environment. Heat transfer may be poor in high vacuum and good in low vacuum. Consequently, variable resistance magnitude may be read out to determine the vacuum level.

Performance of the microbolometer device can be enhanced by using an innovated material with a low device resistance and a high TCR value to provide an infrared detector with a high sensitivity. Systems and methods provide an integrated microbolometer 100 IR focal plane array (FPA) 110 and vacuum sensor and method of fabrication suitable for high-volume commercial vacuum package.

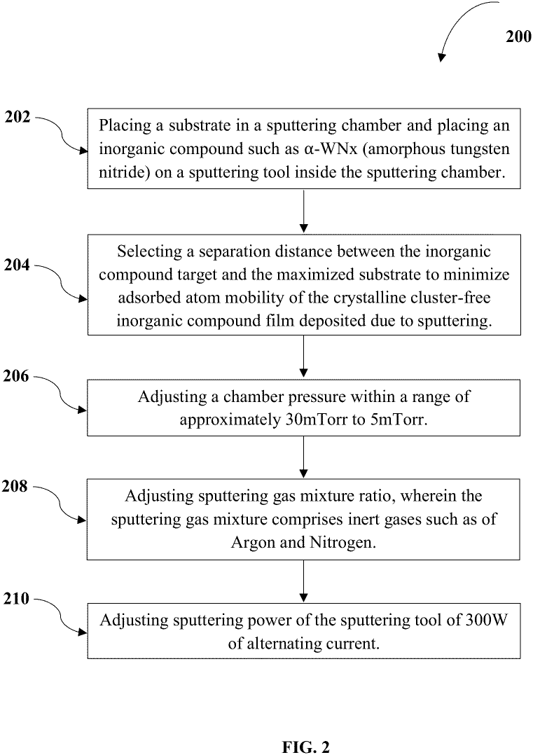

FIG. 2 illustrates an exemplary process of fabricating a crystalline cluster-free inorganic compound such as αWNx (amorphous tungsten nitride) film in accordance with an embodiment of the present disclosure. A process 200 of fabricating a crystalline cluster-free inorganic compound such as αWNx (amorphous tungsten nitride) film may be initiated at step 202 involving placement of a substrate in a sputtering chamber and placement of an inorganic compound such as αWNx (amorphous tungsten nitride) on a sputtering tool inside the sputtering chamber.

Process 200 of fabricating a crystalline cluster-free inorganic compound such as αWNx (amorphous tungsten nitride) film can be initiated at step 202 that pertains to placing a substrate in a sputtering chamber, and inorganic compound such as α-WNx (amorphous tungsten nitride) on a sputtering tool inside the sputtering chamber.

Step 204 pertains to selecting a separation distance between the inorganic compound target and the maximized substrate to minimize adsorbed atom mobility of the crystalline cluster-free inorganic compound film deposited due to sputtering.

Step 206 pertains to adjusting a chamber pressure within a range of approximately 30 mTorr to 5 mTorr. Further, step 208 pertains to adjusting sputtering gas mixture ratio, wherein the sputtering gas mixture comprises inert gases such as of Argon and Nitrogen. Step 210 pertains to adjusting sputtering power of the sputtering tool of 300W of alternating current. In an embodiment, a system for advanced microbolometer performance is provided comprising an absorber element and a detector comprising a film coated on at least one side of the absorber element. The detector detects variation in temperature of the absorber element and changes electrical resistance in response to the detected variation. The film is an inorganic compound. The inorganic compound is α-WNx comprising amorphous tungsten nitride. The absorber element varies temperature responsive to IR (infrared radiation) incident on the absorber element. The film is dangled over a readout integrated circuit (ROIC) at a height of two to three microns. The microbolometer further comprises electrodes coupled to a silicon substrate. The coupling of the electrodes to the substrate provides structural support for the dangled inorganic compound. The electrodes further provide electrical connectivity.

In another embodiment, a method for fabricating an alloy film. The method comprises placing a substrate in a sputtering chamber, placing a Tungsten target in the sputtering chamber on a sputtering tool, and selecting a separation distance between the Tungsten target and the substrate. The method further comprises adjusting a chamber pressure, selecting a sputtering gas mixture ratio, and selecting a sputtering power profile for the sputtering tool of 300W of alternating current. The alloy film is a crystalline cluster-free amorphous Tungsten nitride alloy film. Selecting the separation distance between the Tungsten target and the maximized substrate is effected to minimize absorbed atom mobility of the crystalline cluster-free amorphous Tungsten nitride alloy film produced from the sputtering. The method of further comprises adjusting the chamber pressure within a range of about 30mTorr to 5mTorr, inclusive. The method further comprises selecting the sputtering gas mixture ratio of Argon to Nitrogen.

In yet another embodiment, a system for measuring radiant heat via a material having a temperature-dependent electrical resistance is provided. The system comprises a bolometer, an absorber element, and a film that determines temperature changes associated with the absorber element, and changes electrical resistance in response to the changed temperature. The absorber element is directed to absorbing infrared radiation. The film is a αWNx metal film and is suspended above a substrate. The αWNx film is made of at least amorphous tungsten hydride. The αWNx film exhibits properties with a temperature coefficient of resistance (TCR) of about -1.9%/°C. The microbolometer is promoted for use as a vacuum sensor relying on variations in resistivity against heat dissipation. The deposition process of the αWNx is compatible with at least one fabrication process for complementary metal-oxide-semiconductor (CMOS).

What is claimed is:

1. A system for advanced microbolometer performance, comprising
an absorber element; and
a detector comprising a film coated on at least one side of the absorber element that:
detects variation in temperature of the absorber element, and
changes electrical resistance in response to the detected variation.

2. The system of claim 1, wherein the film is an inorganic compound.

3. The system of claim 2, wherein the inorganic compound is αWNx comprising amorphous tungsten nitride.

4. The system of claim 1, wherein the absorber element varies temperature responsive to IR (infrared radiation) incident on the absorber element.

5. The system of claim 1, wherein the film is dangled over a readout integrated circuit (ROIC) at a height of two to three microns.

6. The system of claim 1, wherein the microbolometer further comprises electrodes coupled to a silicon substrate.

7. The system of claim 6, wherein the coupling of the electrodes to the substrate provides structural support for the dangled inorganic compound.

8. The system of claim 6, wherein the electrodes further provide electrical connectivity.

9. A method for fabricating an alloy film, the method comprising:
placing a substrate in a sputtering chamber;
placing a Tungsten target in the sputtering chamber on a sputtering tool;
selecting a separation distance between the Tungsten target and the substrate
adjusting a chamber pressure;
selecting a sputtering gas mixture ratio; and
selecting a sputtering power profile for the sputtering tool of 300W of alternating current.

10. The method of claim 9, wherein the alloy film is a crystalline cluster-free amorphous Tungsten nitride alloy film.

11. The method of claim 9, wherein selecting the separation distance between the Tungsten target and the maximized substrate is effected to minimize absorbed atom mobility of the crystalline cluster-free amorphous Tungsten nitride alloy film produced from the sputtering.

12. The method of claim 9, further comprising adjusting the chamber pressure within a range of about 30mTorr to 5mTorr, inclusive.

13. The method of claim 9, further comprising selecting the sputtering gas mixture ratio of Argon to Nitrogen.

14. A system for measuring radiant heat via a material having a temperature-dependent electrical resistance, comprising:
a bolometer;
an absorber element; and
a film that:
determines temperature changes associated with the absorber element, and
changes electrical resistance in response to the changed temperature.

15. The system of claim 14, wherein the absorber element is directed to absorbing infrared radiation.

16. The system of claim 14, wherein the film is a αWNx metal film and is suspended above a substrate.

17. The system of claim 16, wherein the αWNx film is made of at least amorphous tungsten hydride.

18. The system of claim 16, wherein the αWNx film exhibits properties with a temperature coefficient of resistance (TCR) of about -1.9%/°C.

19. The system of claim 14, wherein the microbolometer is promoted for use as a vacuum sensor relying on variations in resistivity against heat dissipation.

20. The system of claim 16, wherein a deposition process of the αWNx is compatible with at least one fabrication process for complementary metal-oxide-semiconductor (CMOS).
